(19) United States
(12) Patent Application Publication
(10) Pub. No.: US 2024/0216952 A1
(43) Pub. Date: Jul. 4, 2024

(54) ULTRASONIC TRANSDUCER, FABRICATION METHOD THEREOF AND ULTRASONIC PROBE APPLYING THE SAME

(71) Applicant: Qisda Corporation, Taoyuan City (TW)

(72) Inventor: Fu-Sheng JIANG, Taoyuan City (TW)

(73) Assignee: Qisda Corporation, Taoyuan City (TW)

(21) Appl. No.: 18/527,474

(22) Filed: Dec. 4, 2023

(30) Foreign Application Priority Data
Jan. 3, 2023 (TW) 112100085

(51) Int. Cl. B06B 1/06; H10N 30/87

(52) U.S. Cl. CPC B06B 1/0629; H10N 30/875

(57) ABSTRACT

An ultrasonic transducer includes an ultrasonic transducer unit array and a circuit layer. The ultrasonic transducer unit array includes: a plurality of first array units and a plurality of second array units. At least two adjacent ones of the first array units are arranged along a first direction to form a first series string; at least two adjacent ones of the second array units are arranged along a second direction to form a second series string; the first series string and the second series string are intersected; and the first direction and the second direction form a non-180° angle. The circuit layer includes a first bridging unit connected in series with the first array units; and a second bridging unit connected in series with the second array units. The second bridging unit and the first bridging unit are not directly electrically connected to each other.

This application claims the benefit of Taiwan application Serial No. 112100085, filed Jan. 3, 2023, the subject matter of which is incorporated herein by reference.

### BACKGROUND OF THE DISCLOSURE

### Field of the Disclosure

The disclosure relates in general to an ultrasonic transducer and an ultrasonic probe applying the same, and more particularly to an ultrasonic transducer with a two-dimensional (2D) array structure and an ultrasonic probe applying the same.

### Description of the Related Art

Ultrasonic transducers (or ultrasonic probes) have the advantages of instant imaging, no radiation damage, and low cost, and are often used in diagnostic medical equipment. In recent years, due to the progress and development of micro-electro-mechanical-system (MEMS) technology, ultrasonic technology has been brought into the new field of micromachined ultrasonic transducer (MUT), which has expanded the applications of the ultrasonic transducers to other fields, such as head-mounted virtual reality (VR), fingerprint biometrics and other medical applications.

The traditional ultrasonic probe adopts a one-dimensional array structure, in which a plurality of ultrasonic generating units are arranged in parallel on a substrate, and a two-dimensional ultrasonic image is constructed by receiving and calculating the amplitude change of the wave that is generated by reflecting one-dimensional signal generated by the ultrasonic generating units. Recently, ultrasonic generating units can be assembled into a 2D array structure to provide scanning waves in different dimensions (for example, in different directions or in different lines). Images of different sections of the object can be observed, by rotating or translating the 2D array structure, and then these sectional (2D) images can be reconstructed into a three-dimensional (3D) image through computer software.

When the ultrasonic probe adopts the one-dimensional array structure, since each ultrasonic generating unit can be grounded through a common grounding layer between these ultrasonic generating units and the substrate, thus each of the ultrasonic generating units has the same ground reference potential, and is less prone to ground loop interference.

However, when the ultrasonic probe adopts the two-dimensional structure (taking a row-column array (RCA) ultrasonic transducer as an example), since the electrodes of the ultrasonic generating units are arranged in rows and columns are arranged crosswise, thus the grounding electrode can only be arranged around the ultrasonic generating unit array due to the space constraints, and it is impossible to directly set a common grounding layer on the ultrasonic generating unit array. Moreover, due to the complicated wiring arrangement in the ultrasonic generating unit array, these ultrasonic generating units may have different current loops for grounding current, so that the reference potential on the grounding points of these ultrasonic generating units may be variables, which may cause electromagnetic susceptibility (EMS) signal interference.

Therefore, there is a need to provide an advanced ultrasonic transducer and an ultrasonic probe applying the same to overcome the drawbacks of the prior art.

### SUMMARY OF THE DISCLOSURE

One embodiment of the present disclosure is to provide an ultrasonic transducer, wherein the ultrasonic transducer includes an ultrasonic transducer unit array and a circuit layer. The ultrasonic transducer unit array includes: a plurality of first array units and a plurality of second array units. At least two adjacent ones of the first array units are arranged along a first direction to form a first series string; at least two adjacent ones of the second array units are arranged along a second direction to form a second series string; the first series string and the second series string are intersected; and the first direction and the second direction form a non-180° angle. The circuit layer is disposed on one side of the ultrasonic transducer unit array and includes a first bridging unit and a second bridging unit. The first bridging unit is connected in series with the first array units; and the second bridging unit is connected in series with the second array units. The second bridging unit and the first bridging unit are not directly electrically connected to each other.

Another embodiment of the present disclosure is to provide an ultrasonic probe, wherein the ultrasonic probe includes a casing, an ultrasonic transducer unit array and a circuit layer. The ultrasonic transducing unit array is arranged on one side of the casing and includes a plurality of first array units and a plurality of second array units. At least two adjacent ones of the first array units are arranged along a first direction to form a first series string; at least two adjacent ones of the second array units are arranged along a second direction to form a second series string; the first series string and the second series string are intersected; and the first direction and the second direction form a non-180° angle. The circuit layer is disposed on one side of the ultrasonic transducer unit array and includes a first bridging unit and a second bridging unit. The first bridging unit is connected in series with the first array units; and the second bridging unit is connected in series with the second array units. The second bridging unit and the first bridging unit are not directly electrically connected to each other.

According to the above-mentioned embodiments, this disclosure provides an ultrasonic transducer with a 2D ultrasonic transducer unit array and an ultrasonic probe applying the same. A circuit layer arranged on one side of the ultrasonic transducer unit array and having two types of bridging units that are electrically isolated from each other is applied, using these two bridging units to respectively connect the ultrasonic transducer units of the 2D ultrasonic transducer unit array in series, to form at least one first series string and at least one second series string respectively extending along two different directions.

Since the wires used to connect each ultrasonic transducer unit have been integrated on one side of the ultrasonic transducer unit array by the circuit layer. Therefore, a common grounding layer can be allowed to be directly arranged on the other side of the ultrasonic transducer unit array opposite to the circuit layer. By this approach, since each of the ultrasonic transducer units can be directly or indirectly electrically connected to the common grounding layer, thus these ultrasonic transducer units may have the same ground reference potential, thereby ground loop interference occurred there between greatly can be reduced, and the EMS signal interference subjected by the ultrasonic transducer can be reduced significantly.

### BRIEF DESCRIPTION OF THE DRAWINGS

The above and other aspects of the disclosure will become better understood with regard to the following detailed description of the preferred but non-limiting embodiment(s). The following description is made with reference to the accompanying drawings:

FIG. 1A is a perspective view illustrating an ultrasonic transducer, according to one embodiment of the present disclosure;

FIG. 1B is a top view illustrating the ultrasonic transducer as depicted in FIG. 1A;

FIG. 1C is an enlarged top view illustrating the partial structure of the ultrasonic transducer according to FIG. 1B;

FIG. 2A is a cross-sectional view illustrating the ultrasonic transducer taking along a cutting line A1 as depicted in FIG. 1C;

FIG. 2B is a cross-sectional view illustrating the ultrasonic transducer taking along a cutting line A2 as depicted in FIG. 1C;

FIG. 3A is a cross-sectional view illustrating the ultrasonic transducer taking along a cutting line A1 as depicted in FIG. 1C, according to another embodiment of the present disclosure;

FIG. 3B is a cross-sectional view illustrating the ultrasonic transducer taking along a cutting line A2 as depicted in FIG. 1C, according to another embodiment of the present disclosure;

FIG. 4A is a top view illustrating an ultrasonic transducer, according to yet another embodiment of the present disclosure;

FIG. 4B is an enlarged top view illustrating the partial structure of the ultrasonic transducer according to FIG. 4A; and

FIG. 5 is a schematic diagram illustrating an assembly of an ultrasonic probe according to one embodiment of the present specification.

### DETAILED DESCRIPTION OF THE DISCLOSURE

The present disclosure provides an ultrasonic transducer and an ultrasonic probe applying the same to improve the problems caused by the ground loop interference and EMS signal interference subjected by the ultrasonic transducer. The above and other aspects of the disclosure will become better understood by the following detailed description of the preferred but non-limiting embodiment(s). The following description is made with reference to the accompanying drawings.

Several embodiments of the present disclosure are disclosed below with reference to accompanying drawings. However, the structure and contents disclosed in the embodiments are for exemplary and explanatory purposes only, and the scope of protection of the present disclosure is not limited to the embodiments. It should be noted that the present disclosure does not illustrate all possible embodiments, and anyone skilled in the technology field of the disclosure will be able to make suitable modifications or changes based on the specification disclosed below to meet actual needs without breaching the spirit of the disclosure. The present disclosure is applicable to other implementations not disclosed in the specification.

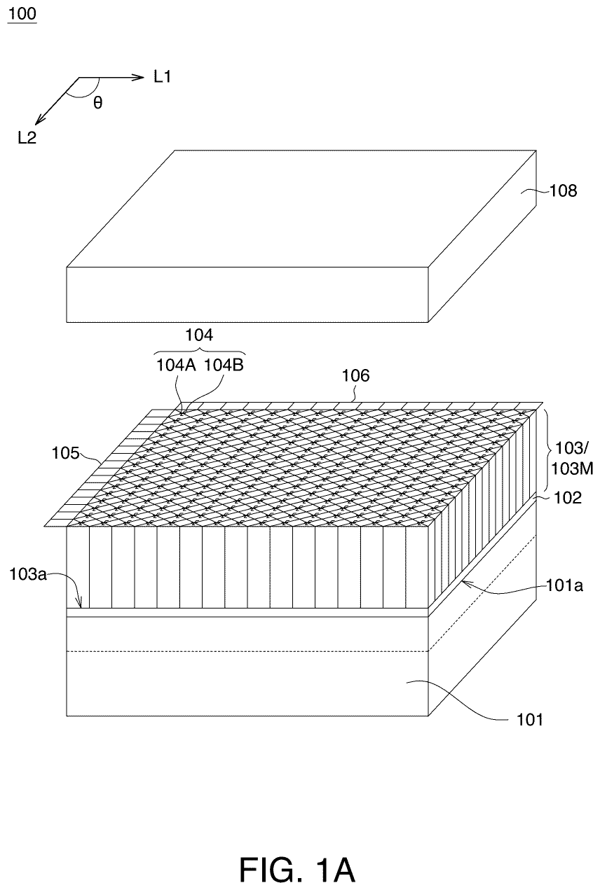

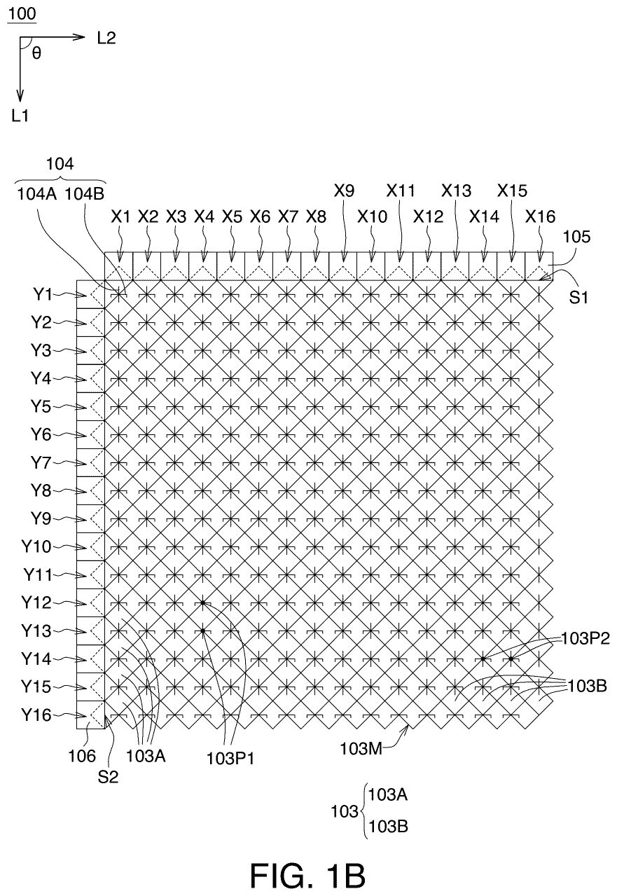

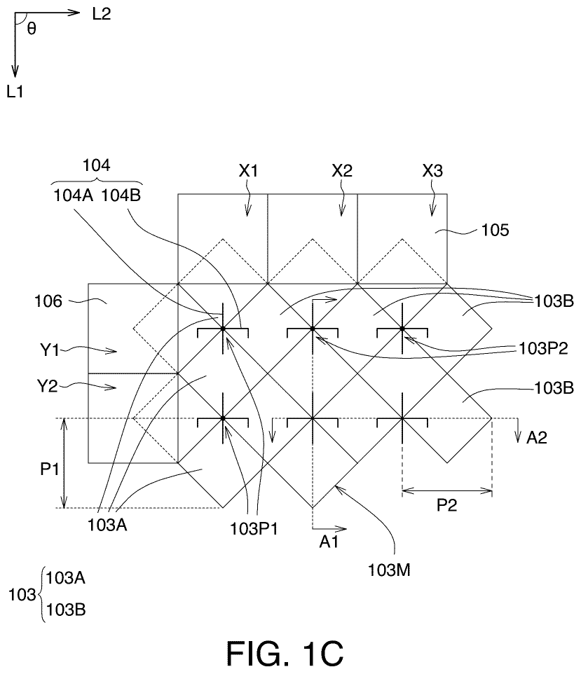

Referring to FIGS. 1A to 1C, FIG. 1A is a perspective view illustrating an ultrasonic transducer 100, according to one embodiment of the present disclosure; FIG. 1B is a top view illustrating the ultrasonic transducer 100 as depicted in FIG. 1A; and FIG. 1C is an enlarged top view illustrating the partial structure of the ultrasonic transducer 100 according to FIG. 1B. The ultrasonic transducer 100 includes: an acoustic impedance matching layer 101 (The acoustic impedance matching layer can be optional, for example, setting the acoustic impedance matching layer 101 is not essential, since thin film acoustic impedance close to that of human tissue can be obtained by using a MUT; the acoustic impedance matching layer 101 may be omitted, because applying underwater ultrasonic transducers with high voltage drive can meet the needs of penetration depth. However, the ultrasonic transducer including the acoustic impedance matching layer 101 has better ultrasonic penetration to water and human tissue), a grounding layer 102, an ultrasonic transducer unit array 103, a circuit layer 104, a plurality of first wires 105, a plurality of second wires 106, and a backing layer 108.

Wherein, the grounding layer 102 is disposed on a surface 101a of the acoustic impedance matching layer 101. The ultrasonic transducer unit array 103 is disposed on the grounding layer 102 and electrically connected to the grounding layer 102 directly or indirectly. The circuit layer 104 is disposed on the side of the ultrasonic transducer unit array 103 away from the grounding layer 102, and is electrically connected to the ultrasonic transducer unit array 103. The backing layer 108 is disposed above the circuit layer 104 (i.e., on a side of the circuit layer 104 away from the ultrasonic transducer unit array 103). If there is an acoustic lens, it is disposed on the side of the ultrasonic transducer unit array 103 opposite to the circuit layer 104 (i.e., the side of the ultrasonic transducer unit array 103 away from the circuit layer 104).

In some embodiments of the present disclosure, the acoustic impedance matching layer 101 may be an acoustic matching layer arranged between the ultrasonic transducer unit (e.g. piezoelectric ceramics) array 103 of the ultrasonic transducer 100 and the external environment E (such as, air), which has the function of matching the acoustic resistances of the ultrasonic transducer unit array 103 and the external environment E, so that the ultrasonic waves generated by the ultrasonic transducer unit array 103 can be effectively transmitted to the external environment E (e.g., air).

Considering weather resistance and reliability, the material used to form the acoustic impedance matching layer 101 may include a composite material made of polymer resin and hollow powder. However, the structure and material of the acoustic impedance matching layer 101 are not limited thereto. For example, in some other embodiments, the acoustic impedance matching layer 101 may be a multi-layer structure. For example, in some embodiments of this disclosure, the acoustic impedance matching layer 101 may be an acoustic matching layer including one or more layers coupled to the ultrasonic transducer array 103 (or the grounding layer 102) that are composed of multiple materials with different or the same acoustic impedance (Z).

The grounding layer 102 is disposed on the surface 101a of the acoustic impedance matching layer 101 away from the external environment E. In one embodiment of the present disclosure, the grounding layer 102 is a layer of conductive material, which directly or indirectly electrically connected with the ultrasonic transducer unit array 103. For example, in the present embodiment, the grounding layer 102 can be a patterned conductive layer having a surface 102a substantially the same size as the ultrasonic transducer array 103 and directly or indirectly connected to the ultrasonic transducer array 103. If the acoustic impedance matching layer 101 is made of conductive material, such as conductive silver glue, it can be combined with the grounding layer 102 to provide the same function.

The ultrasonic transducer unit array 103 is arranged above the surface 102a of the grounding layer 102 and is electrically connected to the grounding layer 102 directly or indirectly. The ultrasonic transducer unit array 103 includes a plurality of first array units 103A and a plurality of second array units 103B. At least two or more adjacent ones of the plurality of first array units 103A are arranged along a first direction L1 (for example, a direction parallel to the Y axis) to form at least one first series string (for example, the first series string X1). At least two or more adjacent ones of the second array units 103B are arranged along a second direction L2 (for example, the direction parallel to the X axis) to form at least one second series string (for example, the second series string Y1). Wherein, the first direction L1 and the second direction L2 form an angle Θ which is not 180° (also referred to as a non-180° angle, such as an angle of 90°), and the first series string X1 and the second series string Y1 are intersected with each other.

With the same arrangement, a plurality of the first series strings (for example, the plurality of the first series strings X1-X16) parallel to each other and electrically isolated from each other and a plurality of the second series strings (for example, the plurality of the second series strings Y1-Y16) parallel to each other and electrically isolated from each other can be formed on the surface 102a of the grounding layer 102. The first array units 103A disposed in the same first series string (e.g. each one of the first series strings X1-X16) have the same first pitch P1; the second array units 103A disposed in the same second series string (e.g., each one of the second series strings Y1-Y16) have the same second pitch P2. In some embodiments of the present disclosure, the first pitch P1 is greater than the second pitch P2. In some other embodiments, the first pitch P1 is substantially equal to the second pitch P2. In yet other embodiments, the first pitch P1 and the second pitch P2 may be different.

In detail, as shown in FIG. 1B, the ultrasonic transducer unit array 103 may be a rectangular array, or other arrays such as a triangular array, a pentagonal array, and a hexagonal array, but not limited thereto. The plurality of first array units 103A are 256 (16×16) isolated diamond patterns formed by cutting the piezoelectric material layer 103M. Wherein, every 17 first array units 103A (the diamond pattern) are arranged along the first direction L1 (e.g., the direction parallel to the Y axis) to form 16 parallel first series strings X1-X16. Each of the first array units 103A (each diamond pattern) has two first vertices 103P1 respectively connect with other two adjacent first vertices of tow other ones of the first array units 103A arranged in the same row (for example, in the first sequence string X1). For example, two first vertices 103P1 respectively belong two adjacent ones of the first array units 103A (the diamond patterns) arranged in the same row (e.g., in the first sequence string X1) are tip to tip connected with each other, along the first directions L1.

The plurality of second array units 103B are 256 (16×16) isolated diamond patterns formed by cutting the piezoelectric material layer 103M. Wherein, every 16 second array units 103B (the diamond patterns) are arranged along the second direction L2 (e.g., the direction parallel to the X axis) to form 16 parallel second series strings Y1-Y16. Each of the second array units 103B (each diamond pattern) has two second vertices 103P2 respectively connect with other two adjacent second vertices of tow other ones of the second array units 103B arranged in the same row (for example, in the second sequence string Y1). For example, two second vertices 103P2 respectively belong two adjacent ones of the second array units 103B (the diamond patterns) arranged in the same row (e.g., in the second sequence string Y1) are tip to tip connected with each other, along the second directions L2.

The piezoelectric material constituting the piezoelectric material layer 103M may be made of lead zirconate titanate (also referred to as “PZT ceramic”). However, in some embodiments of the present disclosure, the piezoelectric material constituting the piezoelectric material layer 103M is not limited thereto. For example, single crystal ferroelectric relaxors (such as, single crystal lead magnesium niobate-lead titanate (PMN-PT)) or other synthetic materials with piezoelectric properties (such as, polyvinylidene fluoride (PVDF), poly (vinylidenefluoride-co-trifluoroethylene) (PVDF-TrFE) and/or one or more other PVDF copolymers) may be used to replace PZT ceramic.

In some other embodiments of the present disclosure, in addition to PZT ceramics, the plurality of first array units 103A and the plurality of second array units 103B that constitute the ultrasonic transducer array 103 also can be a plurality of piezoelectric micromachined ultrasonic transducer (PMUT) units, a plurality of capacitive micromachined ultrasonic transducer (CMUT) units, or any combination of the above three.

The circuit layer 104 is located on the side of the ultrasonic transducer unit array 103 away from the grounding layer 102, and includes a first bridging unit 104A and a second bridging unit 104B. The first bridging unit 104A is used to connect these first array units 103A in series; the second bridging unit 104B is used to connect these second array units 103B in series; and the first bridging unit 104A and the second bridging unit 104B do not have a direct electrical connection with each other. In some embodiments of the present disclosure, the circuit layer 104 can be, for example, a flexible printed circuit (FPC) board, or a FPC board produced by a micro-electromechanical process or a semiconductor process, but it is not limited thereto.

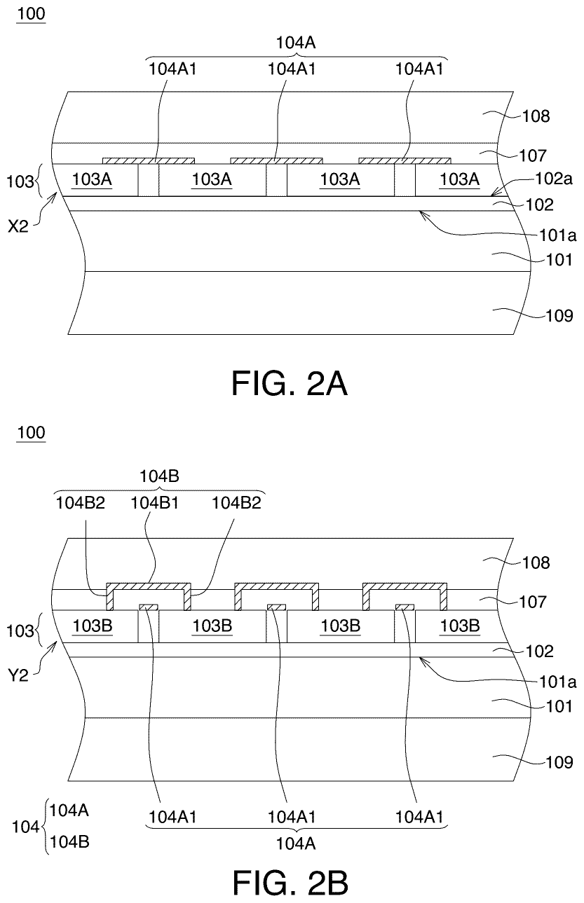

For example, refer to FIGS. 2A and 2B, FIG. 2A is a cross-sectional view illustrating the ultrasonic transducer 100 taking along a cutting line A1 as depicted in FIG. 1C. FIG. 2B is a cross-sectional view illustrating the ultrasonic transducer 100 taking along a cutting line A2 as depicted in FIG. 1C. The first bridging unit 104A may be a patterned metal layer that is formed above the ultrasonic transducer unit array 103, and used to directly or indirectly electrically connected to the first array units 103A in the first series string (for example, the first series sting X2), so as to make the first array units 103A in the first series string (for example, the first series sting X2) connected to each other in series. The second bridging unit 104B may be a patterned structure that is formed above the ultrasonic transducer unit array 103 and is directly or indirectly electrically connected to the second array unit 103B in the second series string (for example, the second series string Y2), so as to make the second array units 103B in the second series string (for example, the second series string Y2) to each other in series. Moreover, the first bridging unit 104A and the second bridging unit 104B can be isolated from each other by an isolation layer 107.

In the present embodiment, the patterned metal layer constituting the first bridging unit 104A includes at least one first channel bridge 104A1, and each first channel bridge 104A1 is electrically connected to two adjacent ones of the first array units 103A (diamond pattern) that are disposed in the same first series string (e.g., the first series string X2), make each first array unit 103A in the same first series string (e.g., the first series string X2) connected to each other in series. And the isolation layer 107 covers the ultrasonic transducer unit array 103.

The patterned metal layer constituting the second bridging unit 104B is formed on the upper surface of the isolation layer 107, and the second bridging unit 104B includes at least one second channel bridge 104B1 and a plurality of conductive plugs (hereinafter referred to as the second connection layer 104B2). Each second channel bridge 104B1 is correspondingly connected to two ones of the plurality of second connection layers 104B2, forming a conductive structure, and across a first bridging unit 104A (a first channel bridge 104A1), so as to electrically connected to two adjacent first array units 103B (diamond patterns) disposed in the same second series string (e.g., the second series sting Y2).

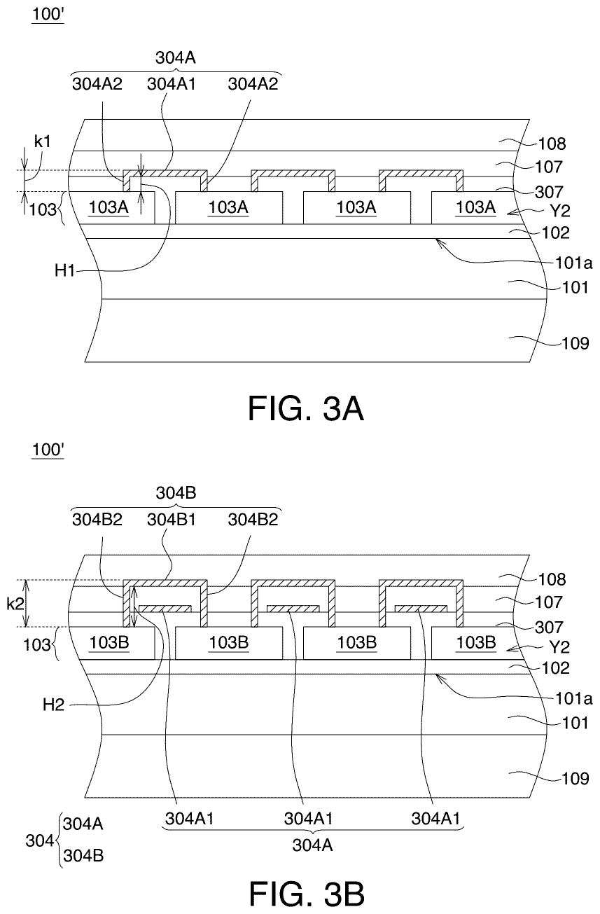

However, the structure of the circuit layer 304 is not limited thereto. For example, refer to FIG. 3A and FIG. 3B, FIG. 3A is a cross-sectional view illustrating the ultrasonic transducer 100′ taking along a cutting line A1 as depicted in FIG. 1C, according to another embodiment of the present disclosure; and FIG. 3B is a cross-sectional view illustrating the ultrasonic transducer 100′ taking along a cutting line A2 as depicted in FIG. 1C, according to another embodiment of the present disclosure. The structure of the circuit layer 304 is similar to that of the circuit layer 104 as shown in FIG. 2A and FIG. 2B, except the structure of the first bridging unit 304A. Since the other structures of the circuit layer 304 are the same as those shown in FIG. 2A and FIG. 2B, thus it will not be described redundantly here.

In the present embodiment, the circuit layer 304 further includes an isolation layer 307 covering all the first array units 103A and the second array units 103B in the ultrasonic transducer array 103. The first bridging unit 304A includes at least one first channel bridge 304A1 and a plurality of conductive plugs (hereinafter referred to as the first connection layer 304A2). Each first channel bridge 304A1 is correspondingly connected to two first connection layers 304A2 to form a conductive structure, and respectively electrically connecting to two adjacent first array units 103A (diamond patterns) disposed in the same first series string (e.g., the first series string X2). Each second channel 304B1 is correspondingly connected to two second connection layers 304B2, forming a conductive structure, and across a first bridging element 304A (first channel 304A1), so as to electrically connected to two adjacent first array units 103B (diamond patterns) disposed in the same second series string (e.g., the second series Y2 string). In some embodiments of the present disclosure, the interval distance H1 between the first channel bridge 304A1 of the first bridging unit 304A and the first array units 103A may be smaller or greater than the interval distance H2 between the second channel bridge 304B1 of the second bridging unit 304B and the second array units 103B. In other embodiments, the length K1 of the first connection layer 304A2 of the first bridging unit 304A may be greater than or smaller than the length K2 of the second connection layer 304B2 of the second bridging unit 304B.

Refer to FIG. 1B again, the plurality of first wires 105 are electrically isolated from each other, and each of the first wires 105 is correspondingly connected to a first series string (for example, the first series string X1). The plurality of second wires 106 are electrically isolated from each other, and each of the second wires 106 is correspondingly connected to a second series string (for example, the second series string Y1). In the present embodiment, the ultrasonic transducer 100 has 16 first wires 105 and 16 second wires 106. Wherein, these 16 first wires 105 are arranged on one side S1 of the ultrasonic transducer array 103 along the direction parallel to the X axis (the second direction L2, and each of which correspondingly is directly or indirectly electrically connected to the first array unit 103A, that belongs to one of the first series strings X1-X16 and is disposed at the end of the first series string close to the side S1. These 16 second wires 106 are arranged on the other side S2 of the ultrasonic transducer array 103 along the direction parallel to the Y axis (second direction L2); and each of which is directly or indirectly electrically connected to the second array unit 103B, that belongs to one of the second series stings Y1-Y16 and is disposed at the end of the second series string close to the side S2.

In addition, each first array unit 103A (the diamond pattern) in the first series X1-X16 and each second array unit 103B (the diamond pattern) in the second series Y1-Y16 are directly or indirectly electrically connected to the underlying grounding layer 102. The controller (not shown) of the ultrasonic transducer 100 can (optionally) control each first array unit 103A in the first series string X1-X16 and each second array unit 103B in the second series string Y1-Y16 by applying a voltage through the first wire 105 and the second wire 106; and then these first array units 103A and the second array units 103B can be deformed by virtue of the piezoelectric effect to generate high-frequency vibration to form a sound wave. If the frequency of the sound wave falls in the ultrasonic range (≥20 kHz), that is, ultrasonic vibration.

Conversely, the controller (not shown) can also control each of the first array units 103A in the first series strings X1-X16 and each of the second array units 103B in the second series Y1-Y16 through the first wire 105 and the second wire 106 respectively, to receive the reflected ultrasonic signal and convert the received ultrasonic signal into a sensing signal by virtue of the positive piezoelectric effect (converting mechanical energy into electrical energy).

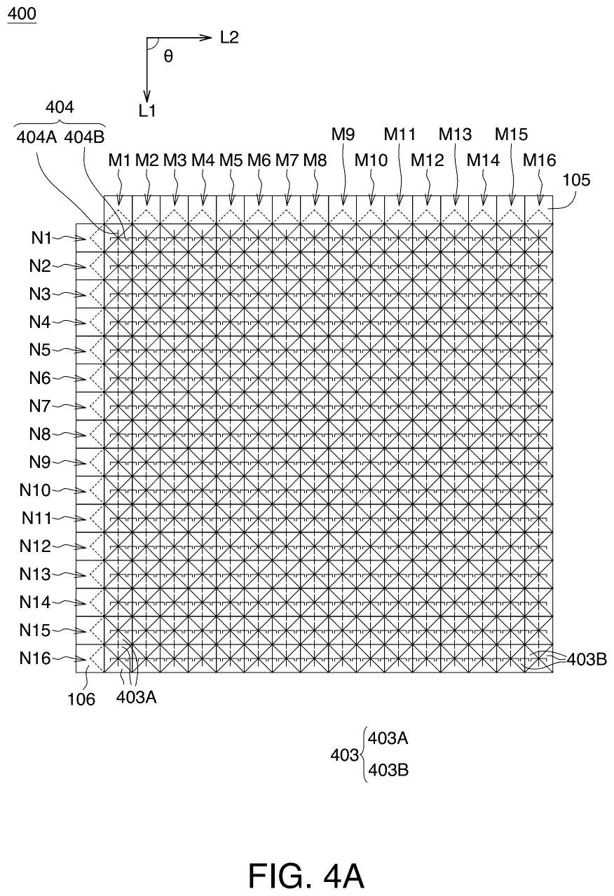

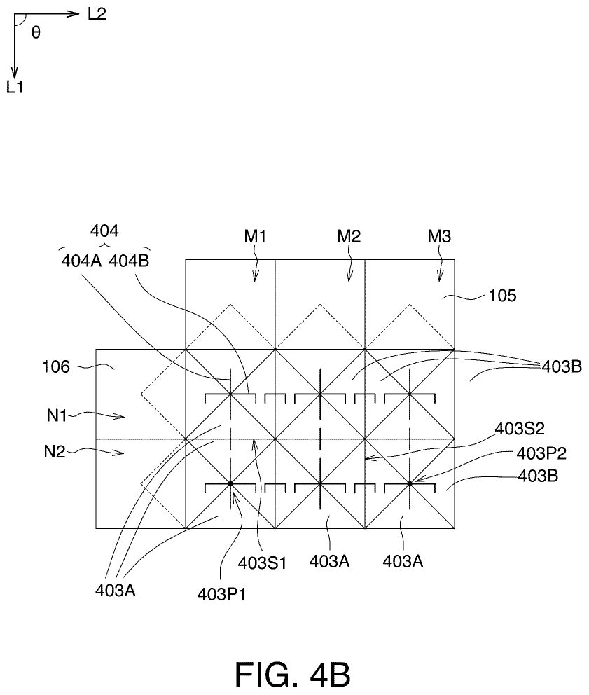

Refer to FIG. 4A and FIG. 4B, FIG. 4A is a top view illustrating an ultrasonic transducer 400, according to yet another embodiment of the present disclosure; and FIG. 4B is an enlarged top view illustrating the partial structure of the ultrasonic transducer 400 according to FIG. 4A. The structure of the ultrasonic transducer 400 is similar to that of the ultrasonic transducer 100 as shown in FIG. 1B, except the difference in shape, arrangement and connection of the plurality of first array units 403A and the plurality of the second array units 403B. Since the other structures of the ultrasonic transducer 400 are the same as those shown in FIG. 1A to FIG. 1C, thus it will not be described redundantly here.

In the present embodiment, the ultrasonic transducer unit array 403 is still (but not limited to) a rectangular array, and the plurality of first array units 403A can be 1024 (32×32) triangular patterns of a piezoelectric material layer isolated from each other. Wherein, every 32 first array units 403A (the triangular patterns) are arranged along the direction parallel to the Y axis (the first direction L1), to form 16 first series strings M1-M16 parallel to each other. Each of the first array units 403A (triangular pattern) has a first vertex 403P1 and a first side 403S1 respectively used to connected to another one adjacent to the first array unit 403A.

In other words, the plurality of first array units 403A in the same first series string (e.g., the first series string X1) are arranged by two ways: one is that, at least two adjacent ones of the first array units 403A disposed in the same first series string (e.g., the first series string X1) are arranged along the first direction L1 and tip to tip connected with their first vertexes 403P1. The other way is that, the first vertex 403P1 of a first array unit 403A is connected to the first side 403S1 of another one adjacent to the first array unit 403A, wherein these two adjacent first array unit 403A are arranged along the first direction L1, and both disposed in the same first series string (e.g., the first series string X1). That kind of arrangement can be understood that, in the same first series string (e.g., the first series string X1), there are at least two adjacent first array units 403A, each of which provides a first vertex 403P1 or a first side 403S1, to connect with that provided by the other.

Every 32 second array units 403B (the triangular patterns) are arranged along the direction parallel to the X axis (the second direction L1), to form 16 second series strings N1-N16 parallel to each other. Each of the second array units 403B (the triangular pattern) has a second vertex 403P2 and a second side 403S2 respectively used to connect to another one adjacent to the second array unit 403B.

Similarly, the plurality of second array units 403B in the same second series string (e.g., the second series string N1) are also arranged by two ways: one is that, at least two adjacent ones of the second array units 403B disposed in the same second series string (e.g., the second series string N1) are arranged along the second direction L2 and tip to tip connected with their second vertexes 403P2. The other way is that, the second vertex 403P1 of a second array unit 403B is connected to the second side 403S2 of another one adjacent to the second array unit 403B, wherein these two adjacent second array units 403B are arranged along the second direction L2, and both disposed in the same second series string (e.g., the second series string XN1). That kind of arrangement can be understood that, in the same second series string (e.g., the second series string N1), there are at least two adjacent second array units 403B, each of which provides a second vertex 403P2 or a second side 403S2, to connect with that provided by the other.

In comparison with the ultrasonic transducer 100 as shown in FIG. 1B, the number of the first array units 403A constituting each one of the first series stings M1-M16 in the ultrasonic transducer 400 is doubled; the number of the second array units 403B constituting each one of the second series strings N1-N16 is also doubled. Therefore, the number of the first bridging units 404A used to connect the first array units 403A in the circuit layer 404 will also be doubled; the number of the second bridging units 404B used to connect the second array units 403B will also be doubled. At the same time, the detection efficiency of the ultrasonic transducer 400 is also increased.

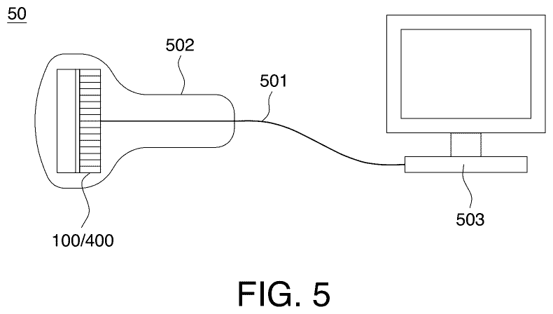

Refer to FIG. 5, FIG. 5 is a schematic diagram illustrating an assembly of an ultrasonic probe 50 according to one embodiment of the present specification. In the present embodiment, the ultrasonic probe 50 includes a cable 501, an ultrasonic transducer 100/400, an ultrasonic identification system 503 and a casing 502. The ultrasonic transducer 100/400 is installed in the casing 502, and is electrically connected with the ultrasonic identification system 503, built in a host computer, through the cable 501. The ultrasonic identification system 503 receives signals from the ultrasonic transducer 100/400 through the cable 501, and then generates characteristic images according to the received signals. In some embodiments, the casing 502 may be a hand-held ultrasonic shell, or a shell in other application fields, such as a detector shell of a fish finder.

According to the above-mentioned embodiments, this disclosure provides an ultrasonic transducer (e.g., the ultrasonic transducer 100) with a 2D ultrasonic transducer unit array and an ultrasonic probe (e.g., ultrasonic probe 50) applying the same. A circuit layer (for example, the circuit layer 104) arranged on one side of the ultrasonic transducer unit array (e.g., the ultrasonic transducing unit array 103) and having two types of bridging units (for example, the first bridging unit 104A and the second bridging unit 104B) that are electrically isolated from each other is applied, using these two type bridging units 104A and 104B to respectively connect the ultrasonic transducer units (e.g., the first array units 103A and the second array units 103B) of the 2D ultrasonic transducer unit array 103 in series, to form two types of series strings (e.g., the first series strings X1-X16 and second series string Y1-Y16) respectively extending along two different directions.

Since the wires (e.g., the first bridging unit 104A and the second bridging unit 104B) used to connect each ultrasonic transducer unit (103A/103B) have been integrated on one side of the ultrasonic transducer unit array 103 by the circuit layer 104. Therefore, a common grounding layer (e.g., the grounding layer 102) can be allowed to be directly arranged on the other side of the ultrasonic transducer unit array 103 opposite to the circuit layer 104. By this approach, since each of the ultrasonic transducer units (103A/103B) can be directly or indirectly electrically connected to the common grounding layer 104, thus these ultrasonic transducer units 100 may have the same ground reference potential, thereby ground loop interference occurred there between greatly can be reduced, and the EMS signal interference subjected by the ultrasonic transducer 100 can be reduced significantly.

While the invention has been described by way of example and in terms of the preferred embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An ultrasonic transducer, comprising:
an ultrasonic transducer unit array, comprising:
a plurality of first array units, wherein at least two adjacent ones of the plurality of first array units are arranged along a first direction to form a first series string; and
a plurality of second array units, wherein at least two adjacent ones of the plurality of second array units are arranged along a second direction to form a second series string; the first series string and the second series string are intersected; and the first direction and the second direction form a non-180° angle; and
a circuit layer, disposed on one side of the ultrasonic transducer unit array and comprising:
a first bridging unit, connected in series with the plurality of first array units; and
a second bridging unit, connected in series with the plurality of second array units; wherein the second bridging unit and the first bridging unit are not directly electrically connected to each other.

2. The ultrasonic transducer according to claim 1, wherein the plurality of first array units comprises a plurality of first vertices; the plurality of second array units comprises a plurality of second vertices; two ones of the plurality of first vertices respectively belong two adjacent ones of the plurality of first array units are arranged along the first direction and tip to tip connected with each other to form the first series string; and two ones of the plurality of second vertices respectively belong two adjacent ones of the plurality of second array units are arranged along the second direction and tip to tip connected with each other to form the second series string.

3. The ultrasonic transducer according to claim 1, further comprising a first wire connecting the first series string and a second wire connecting the second series string.

4. The ultrasonic transducer according to claim 1, wherein the plurality of first array units have a first pitch; the plurality of second array units have a second pitch; and the first pitch is greater than the second pitch.

5. The ultrasonic transducer according to claim 1, further comprising a grounding layer disposed on one side of the ultrasonic transducer array away from the circuit layer, and is electrically connected to the first series string, the second series string or a combination thereof.

6. The ultrasonic transducer according to claim 1, wherein the first bridging unit further comprises a first channel bridge correspondingly electrically connected to the plurality of first array units; and the second bridging unit further comprises a second channel bridge correspondingly electrically connected to the plurality of second array units.

7. The ultrasonic transducer according to claim 6, wherein the first bridging unit further comprises a plurality of first connection layers and a plurality of second connection layers; the plurality of first connection layers disposed between the first channel bridge and the plurality of first array units, and electrically connected to the first channel bridge and the plurality of first array units; and the plurality of second connection layers disposed between the second channel bridge and the plurality of second array units, and electrically connected to the second channel bridge and the plurality of second array units.

8. The ultrasonic transducer according to claim 7, wherein a length of the plurality of first connection layers is smaller or greater than a length of the plurality of second connection layers.

9. The ultrasonic transducer according to claim 6, wherein an interval distance between the first channel bridge and the plurality of first array units is smaller or greater than an interval distance between the second channel bridge and the plurality of second array units.

10. The ultrasonic transducer according to claim 1, wherein at least one of the plurality of first array units and the plurality of second array units comprises a lead zirconate titanate (PZT ceramic) ultrasonic transducer unit, a piezoelectric micromachined ultrasonic transducer (PMUT) unit, a capacitive micromachined ultrasonic transducer (CMUT) unit, or any combination of the above three.

11. An ultrasonic probe, comprising:
a casing; and
an ultrasonic transducing unit array is arranged on one side of the casing, wherein the ultrasonic transducing unit array comprises:
a plurality of first array units, wherein at least two adjacent ones of the plurality of first array units are arranged along a first direction to form a first series string; and
a plurality of second array units, wherein at least two adjacent ones of the plurality of second array units are arranged along a second direction to form a second series string; the first series string and the second series string are intersected; and the first direction and the second direction form a non-180° angle; and
a circuit layer, disposed on one side of the ultrasonic transducer unit array and comprising:
a first bridging unit, connected in series with the plurality of first array units; and
a second bridging unit, connected in series with the plurality of second array units; wherein the second bridging unit and the first bridging unit are not directly electrically connected to each other.

12. The ultrasonic probe according to claim 11, wherein the plurality of first array units comprises a plurality of first vertices; the plurality of second array units comprises a plurality of second vertices; two ones of the plurality of first vertices respectively belong two adjacent ones of the plurality of first array units are arranged along the first direction and tip to tip connected with each other to form the first series string; and two ones of the plurality of second vertices respectively belong two adjacent ones of the plurality of second array units are arranged along the second direction and tip to tip connected with each other to form the second series string.

13. The ultrasonic probe according to claim 11, further comprising a first wire connecting the first series string and a second wire connecting the second series string.

14. The ultrasonic probe according to claim 11, wherein the plurality of first array units have a first pitch; the plurality of second array units have a second pitch; and the first pitch is greater than the second pitch.

15. The ultrasonic probe according to claim 11, further comprising a grounding layer disposed on one side of the ultrasonic transducer array away from the circuit layer, and is electrically connected to the first series string, the second series string or a combination thereof.

16. The ultrasonic probe according to claim 11, wherein the first bridging unit further comprises a first channel bridge correspondingly electrically connected to the plurality of first array units; and the second bridging unit further comprises a second channel bridge correspondingly electrically connected to the plurality of second array units.

17. The ultrasonic probe according to claim 16, wherein the first bridging unit further comprises a plurality of first connection layers and a plurality of second connection layers; the plurality of first connection layers disposed between the first channel bridge and the plurality of first array units, and electrically connected to the first channel bridge and the plurality of first array units; and the plurality of second connection layers disposed between the second channel bridge and the plurality of second array units, and electrically connected to the second channel bridge and the plurality of second array units.

18. The ultrasonic probe according to claim 17, wherein a length of the plurality of first connection layers is smaller or greater than a length of the plurality of second connection layers.

19. The ultrasonic probe according to claim 16, wherein an interval distance between the first channel bridge and the plurality of first array units is smaller or greater than an interval distance between the second channel bridge and the plurality of second array units.

20. The ultrasonic probe according to claim 11, wherein the circuit layer is a FPC board.
